(19) United States
(12) Patent Application Publication
(10) Pub. No.: US 2016/0056164 A1
(43) Pub. Date: Feb. 25, 2016

(54) NONVOLATILE SEMICONDUCTOR MEMORY DEVICE AND METHOD OF MANUFACTURING THE SAME

(71) Applicant: Kabushiki Kaisha Toshiba, Minato-ku (JP)

(72) Inventors: Ken Komiya, Yokkaichi (JP); Noriaki Mikasa, Kuwana (JP)

(73) Assignee: Kabushiki Kaisha Toshiba, Minato-ku (JP)

(21) Appl. No.: 14/628,628

(22) Filed: Feb. 23, 2015

Related U.S. Application Data
(60) Provisional application No. 62/041,481, filed on Aug. 25, 2014.

(51) Int. Cl. H01L 27/115; H01L 21/28; H01L 29/49; H01L 29/423; H01L 29/788; H01L 29/66

(52) U.S. Cl. CPC H01L 27/11521; H01L 29/788; H01L 29/66825; H01L 29/4916; H01L 29/42324; H01L 21/28273

(57) ABSTRACT

According to an embodiment, a nonvolatile semiconductor memory device comprises: a semiconductor substrate; a first gate insulating film; a floating gate electrode; a second gate insulating film; and a control gate electrode. The first gate insulating film is formed on the semiconductor substrate. The floating gate electrode is formed arranged in a first direction on the first gate insulating film. The second gate insulating film is formed on an upper surface and a side surface of the floating gate electrode. The control gate electrode is formed extending in the first direction and facing the upper surface and the side surface of the floating gate electrode via the second gate insulating film. In addition, the floating gate electrode includes boron. Moreover, a concentration of boron in the floating gate electrode is higher with being further from the semiconductor substrate.

### CROSS-REFERENCE TO RELATED APPLICATIONS

This application is based upon and claims the benefit of U.S. Provisional Patent Application No. 62/041,481, filed on Aug. 25, 2014, the entire contents of which are incorporated herein by reference.

### BACKGROUND

1. Field

An embodiment described here relates to a nonvolatile semiconductor memory device and a method of manufacturing the same.

2. Description of the Related Art

A memory cell configuring a nonvolatile semiconductor memory device such as a NAND type flash memory includes a semiconductor layer, a control gate electrode, and a charge accumulation layer. The memory cell changes its threshold voltage according to a charge accumulated in the charge accumulation layer to store a magnitude of this threshold voltage as data. In recent years, enlargement of capacity and raising of integration level has been proceeding in such a nonvolatile semiconductor memory device.

### BRIEF DESCRIPTION OF THE DRAWINGS

FIG. 1 is a schematic plan view of a nonvolatile semiconductor memory device according to a first embodiment.

FIG. 2A is a cross-sectional view taken along the line A-A of FIG. 1.

FIG. 2B is a cross-sectional view taken along the line B-B of FIG. 1.

FIG. 3 is a cross-sectional view showing a manufacturing process of the same nonvolatile semiconductor memory device.

FIG. 4 is a cross-sectional view showing a manufacturing process of the same nonvolatile semiconductor memory device.

FIG. 5 is a cross-sectional view showing a manufacturing process of the same nonvolatile semiconductor memory device.

FIG. 6 is a cross-sectional view showing a manufacturing process of the same nonvolatile semiconductor memory device.

FIG. 7 is a cross-sectional view showing a manufacturing process of the same nonvolatile semiconductor memory device.

FIG. 8 is a cross-sectional view showing a manufacturing process of the same nonvolatile semiconductor memory device.

FIG. 9 is a cross-sectional view showing a manufacturing process of the same nonvolatile semiconductor memory device.

FIG. 10 is a cross-sectional view showing a manufacturing process of the same nonvolatile semiconductor memory device.

FIG. 11 is a cross-sectional view showing a manufacturing process of the same nonvolatile semiconductor memory device.

FIG. 12A is a cross-sectional view showing a manufacturing process of the same nonvolatile semiconductor memory device.

FIG. 12B is a cross-sectional view showing a manufacturing process of the same nonvolatile semiconductor memory device.

FIG. 13 is a schematic cross-sectional view showing a state of etching when concentration of boron in a floating gate electrode is uniform.

FIG. 14 is a schematic cross-sectional view showing a state of etching when concentration of boron in the floating electrode gate is not uniform.

FIG. 15 is a graph showing an etching amount when etching is performed on polysilicon under a plurality of different conditions.

FIG. 16 is a graph showing an etching amount when etching is performed on polysilicon under a plurality of different conditions.

### DETAILED DESCRIPTION

A nonvolatile semiconductor memory device according to an embodiment described below comprises: a semiconductor substrate; a first gate insulating film; a floating gate electrode; a second gate insulating film; and a control gate electrode. The first gate insulating film is formed on the semiconductor substrate. The floating gate electrode is formed arranged in a first direction on the first gate insulating film. The second gate insulating film is formed on an upper surface and a side surface of the floating gate electrode. The control gate electrode is formed extending in the first direction and facing the upper surface and the side surface of the floating gate electrode via the second gate insulating film. In addition, the floating gate electrode includes boron. Moreover, a concentration of boron in the floating gate electrode is higher with being further from the semiconductor substrate.

An embodiment of a nonvolatile semiconductor memory device and a method of manufacturing the same will be described below with reference to the drawings. Note that voltage values and so on shown in the specification are merely illustrative, and may be changed appropriately.

### First Embodiment

### Overall Configuration

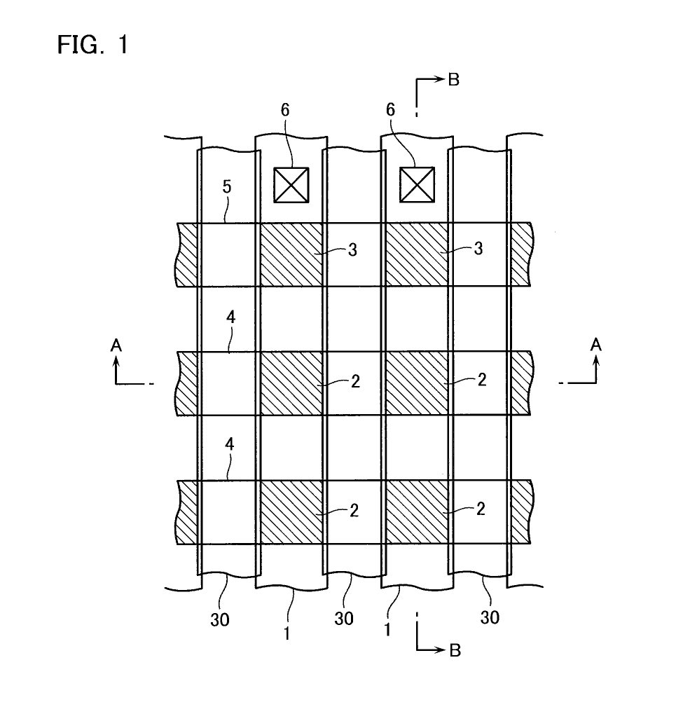

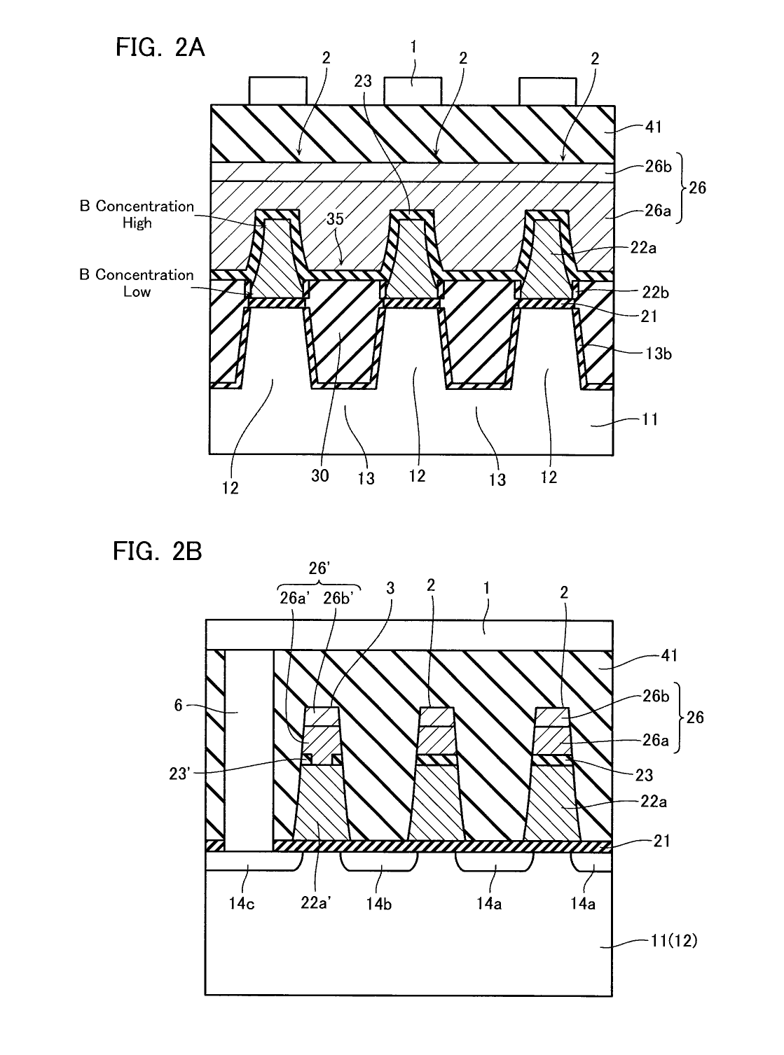

FIG. 1 is a schematic plan view of a nonvolatile semiconductor memory device according to a first embodiment, and FIGS. 2A and 2B are cross-sectional views taken along the lines A-A and B-B, respectively, of FIG. 1.

As shown in FIG. 1, a memory cell array of a NAND type flash memory has a configuration in which a plurality of memory cells 2 and a select transistor 3 are connected in series along a bit line 1. Moreover, a plurality of the memory cells 2 arranged in a direction of extension of a word line 4 (referred to below as “word line direction”) are connected to a common control gate line (word line) 4, and the select transistor 3 is connected to a common select gate line 5. The bit line 1 is connected to each of the select transistors 3 via a bit line contact 6.

As shown in FIG. 2A, the memory cell array includes an element formation region 12 formed on a silicon substrate 11, and this element formation region 12 is partitioned by an element isolation trench 13. As shown in FIG. 2B, the memory cell 2 and the select transistor 3 are formed on this element formation region 12.

In addition, as shown in FIG. 2B, the memory cells 2 adjacent in a direction of extension of the bit line 1 (referred to below as “bit line direction”) share a source-drain diffusion layer 14a on the silicon substrate 11. Similarly, the memory cell 2 and the select transistor 3 adjacent in the bit line direction share a source-drain diffusion layer 14b on the silicon substrate 11. Moreover, the select transistors 3 facing each other sandwiching the bit line contact 6 share a source-drain diffusion layer 14c on the silicon substrate 11.

As shown in FIG. 2A, a floating gate electrode 22a is formed on each of the element formation regions 12 via a first gate insulating film 21 (lower gate insulating film) which is a tunnel insulating film. The floating gate electrode 22a, the first gate insulating film 21, and the element isolation trench 13 undergo patterning simultaneously as will be mentioned later, hence are aligned with each other at side surfaces thereof.

As shown in FIG. 2A, the floating gate electrode 22a according to the present embodiment is formed in a shape having both sides hollowed in an A-A cross-section. That is, a lower surface of the floating gate electrode 22a has a width equal to that of an element formation region 12 surface that the floating gate electrode 22a faces via the first gate insulating film 21. Moreover, the width of the floating gate electrode 22a decreases comparatively steeply from the lower surface to a certain height and decreases comparatively gently from this height to an upper portion. Therefore, the width in the A-A cross-section of the upper portion of the floating gate electrode 22a is smaller compared to that of the lower surface. In addition, at least part of an upper surface of the floating gate electrode 22a includes a surface substantially parallel to the lower surface, and is at least not sharp.

Moreover, in the present embodiment, the floating gate electrode 22a is configured from polysilicon including boron. A concentration of boron in the floating gate electrode 22a differs in a stacking direction, is lower with being closer to the semiconductor substrate 11 (at lower position in the illustration) and is higher with being further from the semiconductor substrate 11 (at hither position in the illustration). Furthermore, the concentration of boron in the floating gate electrode 22a differs by five times or more within the floating gate electrode 22a.

In addition, an insulating film 13b is formed on an inner wall (a bottom surface and side surfaces) of the element isolation trench 13, and an insulating film 22b is formed on a lower side surface of the floating gate electrode 22a. Moreover, an element isolation insulating film 30 is formed inside the element isolation trench 13. Note that an upper surface of the element isolation insulating film 30 is positioned at a height between the upper surface and the lower surface of the floating gate electrode 22a.

As shown in FIG. 2A, a control gate electrode 26 is continuously pattern formed straddling a plurality of the element formation regions 12 in a direction orthogonal to the bit line, and configures the control gate line (word line) 4. Moreover, the control gate electrode 26 faces the upper surface and side surfaces of the floating gate electrode 22a via a second gate insulating film 23 (upper gate insulating film). Furthermore, the control gate electrode 26 is formed so as to be embedded to a concave portion 35 between the floating gate electrodes 22a. Therefore, the control gate electrode 26 contacts a portion of the second gate insulating film 23 covering the upper surface of the element isolation insulating film 30.

The control gate electrode 26 has a two-layer structure of a polycrystalline silicon film 26a and a tungsten silicide (WSi) film 26b. Materials of the films 26a and 26b are not limited to polycrystalline silicon or tungsten silicide, and, for example, a silicide film of polysilicon, and so on, may also be utilized. Note that it is also possible for the tungsten silicide film 26b to be omitted.

As shown in FIG. 2B, the select transistor 3 comprises: a gate electrode 22a′; an insulating film 23′; and a select gate line 26′ (films 26a′ and 26b′). The gate electrode 22a′, the insulating film 23′, and the films 26a′ and 26b′ are respectively formed by films of identical materials to those of each of portions 22a, 23, and 26a and 26b of the memory cell 2. However, due to the second gate insulating film 23′ being partially removed, the select gate line 26′ is directly connected to (short-circuited with) the gate electrode 22a′.

As shown in FIG. 2A, in the nonvolatile semiconductor memory device according to the present embodiment, the control gate electrode 26 is formed on the upper portion and side portions of a plurality of the floating gate electrodes 22a via the second gate insulating film. Therefore, the floating gate electrode 22a and the control gate electrode 26 are faced against each other in a broad area, and capacitive coupling between these floating gate electrode 22a and control gate electrode 26 is suitably increased.

Moreover, in the nonvolatile semiconductor memory device according to the present embodiment, the floating gate electrode 22a includes boron, and the concentration of boron in the floating gate electrode 22a differs in the stacking direction so as to be lower with being closer to the semiconductor substrate and be higher with being further from the semiconductor substrate. Therefore, as will be described later, it is possible to preferentially promote etching of a floating gate electrode 22a side portion while suppressing etching of a floating gate electrode 22a upper portion, in a manufacturing process. As a result, it is possible to broaden a spacing of fellow floating gate electrodes 22a and suitably embed the control gate electrode 26 in the concave portion 35 between the floating gate electrodes 22a while securing a height of the floating gate electrode 22a. This makes it possible for the floating gate electrode 22a and the control gate electrode 26 to be faced against each other in a broad area, and for capacitive coupling of the floating gate electrode 22a and the control gate electrode 26 to be suitably increased.

Moreover, in the nonvolatile semiconductor memory device according to the present embodiment, at least part of the upper surface of the floating gate electrode 22a may be configured to be parallel to the lower surface and may be configured to at least not be sharp. As a result, concentration of an electric field to the floating gate electrode 22a upper portion can be prevented, and leak current can be lowered.

Moreover, in the nonvolatile semiconductor memory device according to the present embodiment, the above-mentioned concentration distribution of boron results in mobility of electrons rising close to the first gate insulating film 21 and mobility of electrons lowering close to the second gate insulating film 23. Therefore, leak current to the control gate electrode 26 can be suitably prevented. Moreover, depletion close to the first gate insulating film 21 can be prevented from occurring, and the nonvolatile semiconductor memory device can be suitably operated.

[Method of Manufacturing]

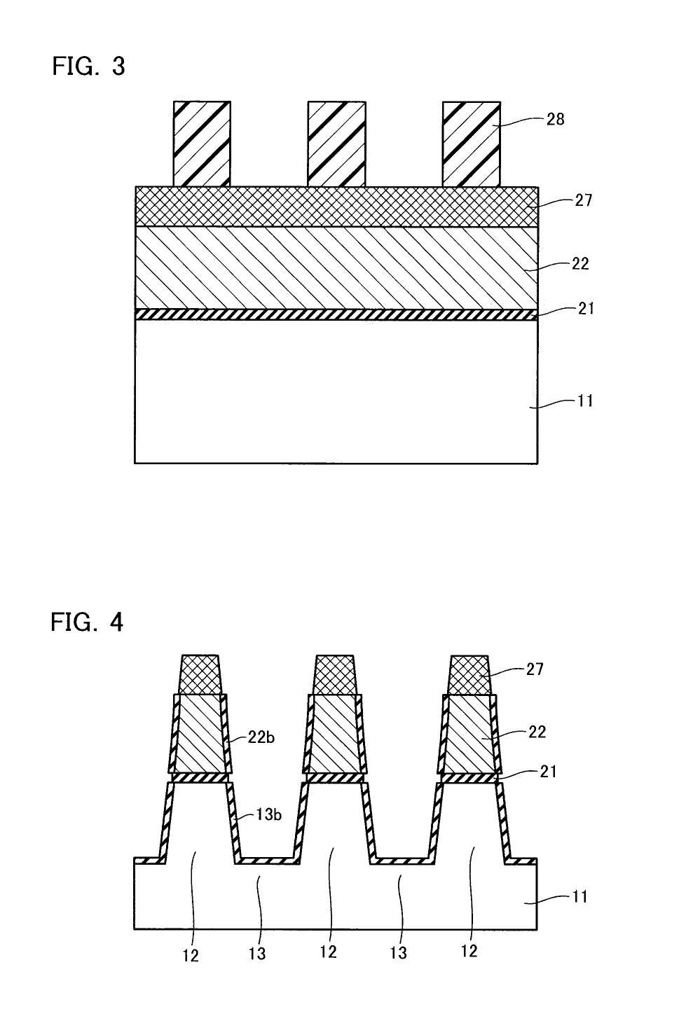

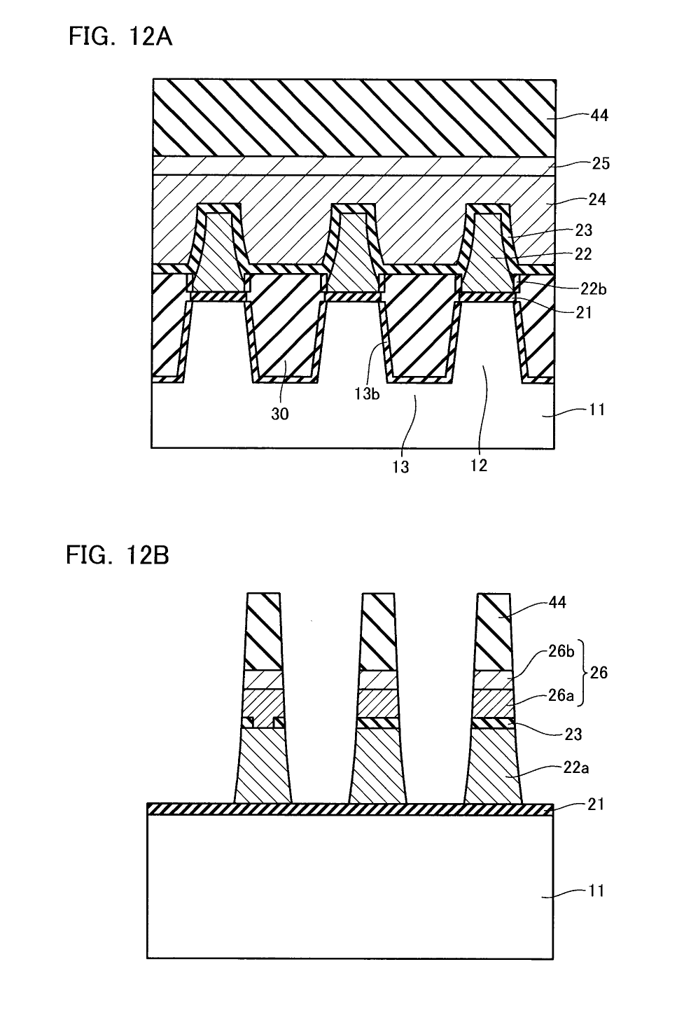

Next, a specific manufacturing process of a NAND type EEPROM according to this embodiment will be described with reference to FIGS. 3 to 11, 12A, and 12B. FIGS. 3 to 11, 12A, and 12B are cross-sectional views each showing a manufacturing process of the nonvolatile semiconductor memory device according to the present embodiment, FIGS. 3 to 11 and 12A are cross-sectional views corresponding to FIG. 2A, and FIG. 12B is a cross-sectional view corresponding to FIG. 2B.

First, as shown in FIG. 3, a silicon oxide film is formed on the silicon substrate 11 as the first gate insulating film 21, a polysilicon film 22 is deposited on this silicon oxide film as a material film of the floating gate electrode 22a, and furthermore, a silicon nitride film 27 is formed as a stopper film in a CMP (chemical mechanical polishing) process. Now, boron is included in the polysilicon film 22. A concentration of this boron is adjusted in the stacking direction so as to be lower with being closer to the silicon substrate 11 and be higher with being further from the silicon substrate 11. Moreover, the concentration of boron in the polysilicon film 22 differs by a maximum of five times or more within the polysilicon film 22. Following this, a resist pattern 28 is formed on the silicon nitride film 27.

Next, as shown in FIG. 4, the silicon nitride film 27, the polysilicon film 22, the first gate insulating film 21, and the silicon substrate 11 are etched using the resist pattern 28 as an etching mask. As a result, the element formation region 12 where the memory cell 2 is formed, and the element isolation trench 13 that partitions this, are formed. Moreover, in this process, the silicon nitride film 27, the polysilicon film 22, and the first gate insulating film 21 are divided in the bit line direction. Now, in the present process, patterning is performed using an identical resist pattern 28 as the mask, hence side surfaces of the polysilicon film 22, the first gate insulating film 21, and the element formation region 12 are aligned with each other. After this, in order to remove damage due to etching, the silicon oxide film 22b is formed on side surfaces of the polysilicon film 22 and the silicon oxide film 13b is formed on side surfaces and a bottom surface of the element isolation trench 13, by a thermal oxidation method.

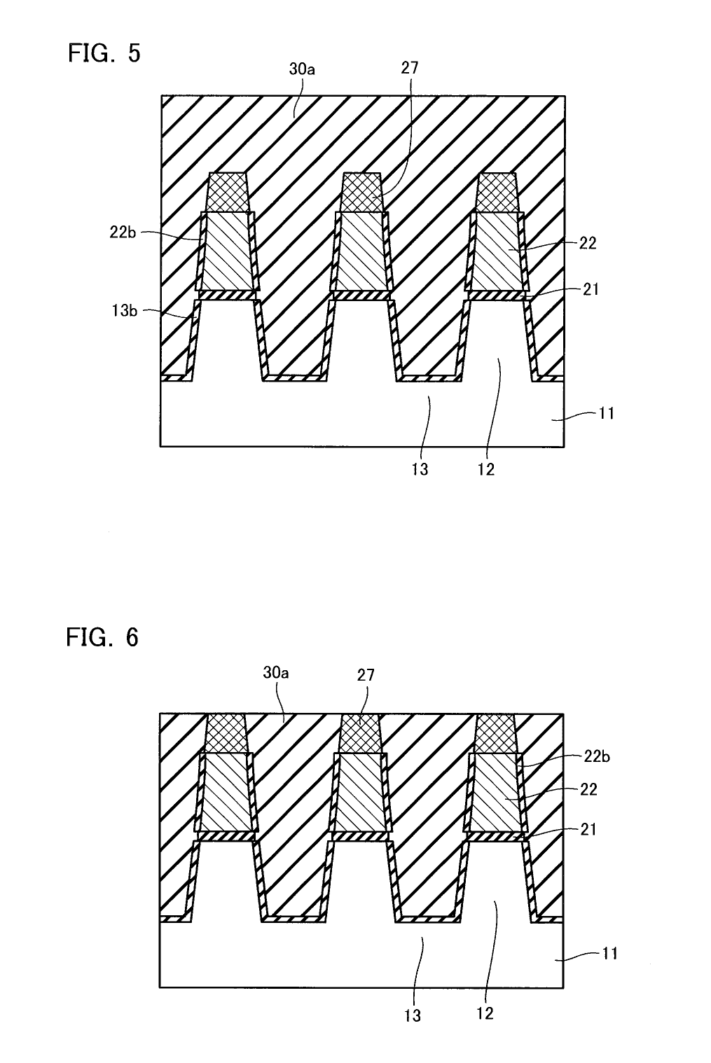

Next, as shown in FIG. 5, a silicon oxide film is formed and adopted as an element isolation insulating film formation layer 30a that forms the element isolation insulating film 30. The element isolation insulating film formation layer 30a is deposited on an entire surface including not only in the element isolation trench 13, but also on the silicon nitride film 27 formed on the element formation region 12.

Next, as shown in FIG. 6, the element isolation insulating film formation layer 30a is removed/planarized to an upper surface of the silicon nitride film 27 by a CMP method using the silicon nitride film 27 as a stopper film.

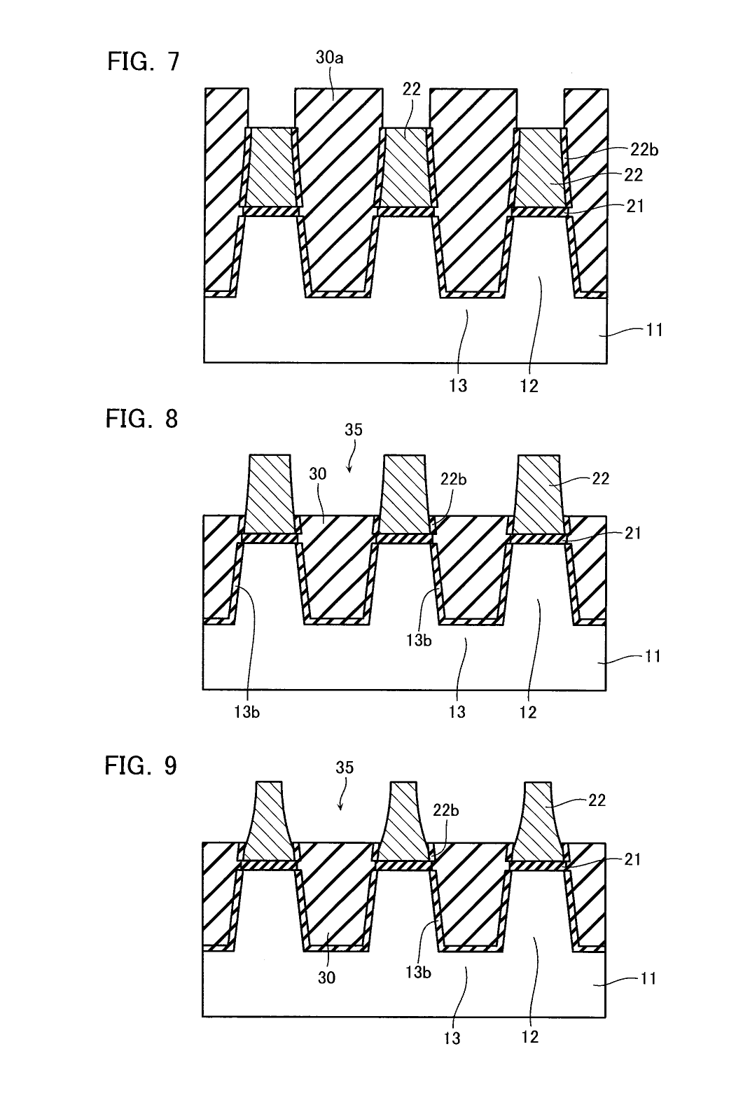

Then, as shown in FIG. 7, the silicon nitride film 27 is removed by phosphating, and an upper surface of the polysilicon film 22 is exposed.

Then, as shown in FIG. 8, part of the element isolation insulating film formation layer 30a and part of the silicon oxide film 22b are removed by etching employing hydrofluoric acid to form the element isolation insulating film 30 and to form the concave portion 35 between the polysilicon films 22. As shown in FIG. 8, in this process, upper surfaces of the element isolation insulating film 30 and the silicon oxide film 22b are formed at a height between an upper surface and a lower surface of the polysilicon film 22, and at least part of the side surface of the polysilicon film 22 is exposed.

Next, as shown in FIG. 9, etching is performed, and at least part of a side portion of the polysilicon film 22 divided in the bit line direction is removed. As a result, a spacing of fellow polysilicon films 22 broadens. Now, as will be mentioned later, when etching is performed on polysilicon including boron, etching rate lowers as concentration of boron rises, and etching rate rises as concentration of boron lowers. Therefore, the polysilicon film 22 according to the present embodiment has a higher etching rate with being closer to the silicon substrate 11 and a lower etching rate with being further from the silicon substrate 11. In addition, a lower portion of the polysilicon film 22 is protected by the element isolation insulating film 30. Therefore, etching progresses mainly in an intermediate portion of the polysilicon film 22, and the polysilicon film 22 is formed in a shape having both sides hollowed. Moreover, the lower portion of the polysilicon film 22 is protected by the element isolation insulating film 30, hence the lower surface of the polysilicon film 22 has a width equal to the element region formation region 12 surface that the polysilicon film 22 faces via the first gate insulating film 21. Moreover, the width of the polysilicon film 22 decreases comparatively steeply from the lower surface to a certain height and decreases comparatively gently from this height to an upper portion. Therefore, the width of the upper portion of the polysilicon film 22 is smaller compared to that of the lower surface. In addition, at least part of the upper surface of the polysilicon film 22 is parallel to the lower surface, and is at least not sharp.

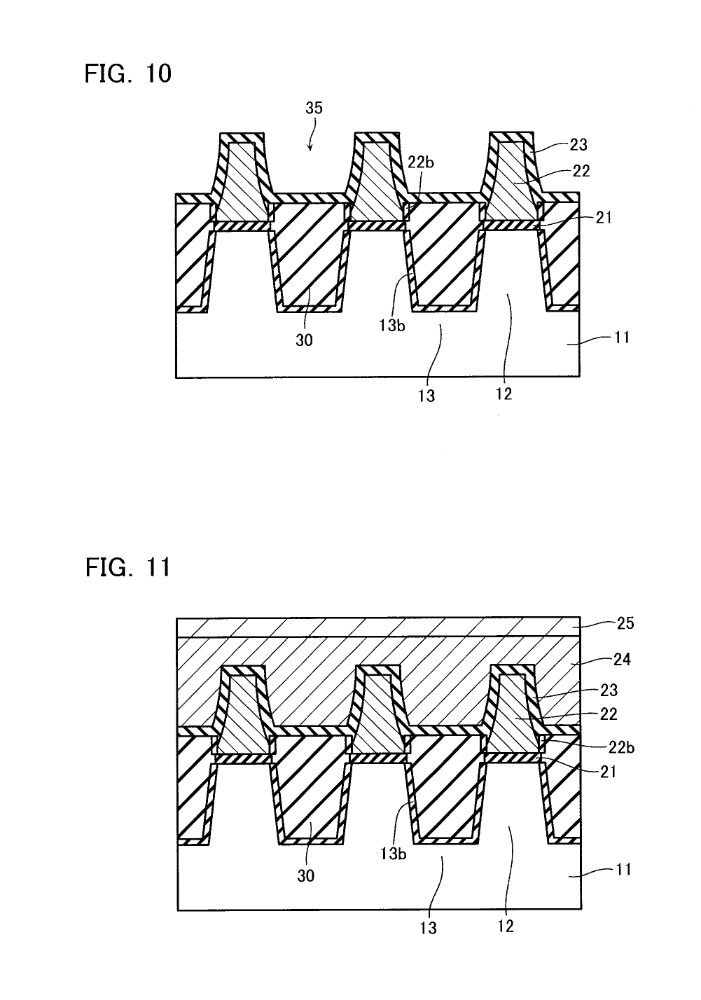

Next, as shown in FIG. 10, an ONO film of a certain thickness is formed on the upper surface and side surfaces of the polysilicon film 22 and on the element isolation insulating film 30 (that is, on an inner surface of the concave portion 35), by a reduced pressure CVD method, as the second gate insulating film 23. The ONO film is an insulating film of a three-layer structure having formed stacked sequentially therein a first silicon oxide film, a silicon nitride film, and a second silicon oxide film. Note that in a region where the select transistor 3 (FIG. 2B) is formed, the second gate insulating film 23 is partially removed to configure such that the polysilicon film 22 and the control gate electrode 26 are short-circuited.

Following this, as shown in FIG. 11, a polycrystalline silicon film 24 and a tungsten silicide film 25 are formed sequentially on this second gate insulating film 23, as materials of the control gate electrode 26.

Next, as shown in FIG. 12A, a mask pattern 44 of a silicon nitride film is formed. This mask pattern 44 is formed by forming a silicon nitride film on the tungsten silicide film 25, and furthermore forming a resist pattern (not illustrated) on this silicon nitride film and etching the silicon nitride film using this resist pattern as a mask. This mask pattern 44 extends in a direction (word line direction) perpendicular to a direction of extension of the element isolation trench 13. Following this, the tungsten silicide film 25, the polysilicon film 24, the second gate insulating film 23, and the polysilicon film 22 undergo patterning using the mask pattern 44 as an etching mask. As a result, as shown in FIG. 12B, the polysilicon film 22 is formed in a shape of the floating gate electrode 22a of each of the memory cells 2, and the polysilicon film 24 and tungsten silicide film 25 are formed in shapes of the films 26a and 26b forming the control gate electrode 26 of each of the memory cells 2.

Then, removal of the silicon nitride film 44, formation of the source-drain diffusion layers 14a, 14b, and 14c by ion implantation/thermal diffusion, formation of an inter-layer insulating film 41, formation of the bit line 1, and formation of the bit line contact 6 are performed, whereby a cell array of a NAND type EEPROM of the kind shown in FIGS. 1, 2A, and 2B is obtained.

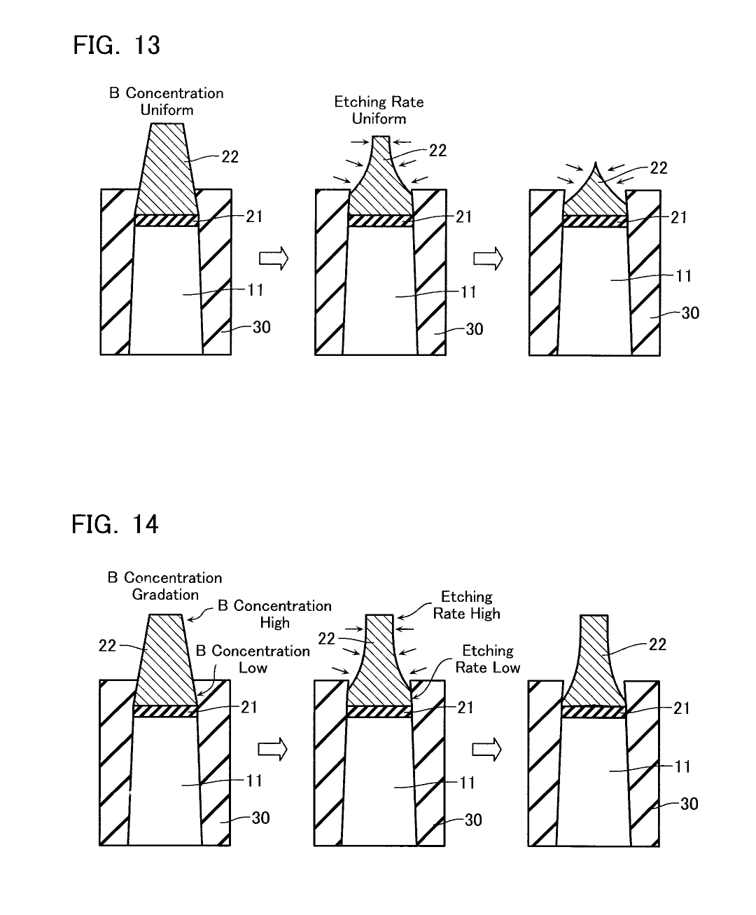

Next, advantages of the method of manufacturing a nonvolatile semiconductor memory device according to the present embodiment will be described with reference to FIGS. 13 and 14. FIG. 13 is a schematic cross-sectional view showing a state of etching when concentration of boron in the polysilicon film 22 forming the floating gate electrode 22a (FIG. 2A) is uniform, and FIG. 14 is a schematic cross-sectional view showing a state of etching when concentration of boron in the polysilicon film 22 is not uniform.

In the method of manufacturing a nonvolatile semiconductor memory device according to the present embodiment, at least part of the side portion of the polysilicon film 22 is removed, and the spacing of fellow polysilicon films 22 is broadened. Therefore, the polycrystalline silicon film 24 is suitably embedded between the polysilicon films 22. This makes it possible for the floating gate electrode 22a and the control gate electrode 26 to be faced against each other in a broad area, and for capacitive coupling between the floating gate electrode 22a and the control gate electrode 26 to be suitably increased.

Now, as shown in FIG. 13, sometimes, when the polysilicon film 22 had become a certain size or less, if it was attempted to remove the side portion of the polysilicon film 22 by etching, and so on, etching ended up progressing isotropically at the upper surface and side surfaces of the polysilicon film 22, and not only the side portion but also the upper portion of the polysilicon film 22 were removed, and a height of the polysilicon film 22 ended up decreasing. Sometimes, in this case, area of the side surface of the floating gate electrode 22a facing the control gate electrode 26 decreases and, conversely, capacitive coupling between the floating gate electrode 22a and the control gate electrode 26 ends up decreasing.

Now, as will be mentioned in detail later, when etching is performed on polysilicon including boron, etching rate lowers as concentration of boron rises, and etching rate rises as concentration of boron lowers. Therefore, as shown in FIG. 14, the polysilicon film 22 according to the present embodiment has a higher etching rate with being closer to the silicon substrate 11 and a lower etching rate with being further from the silicon substrate 11. Therefore, etching of the polysilicon film 22 upper portion is suppressed and reduction of height is also suppressed to suitably secure area of the side portion of the polysilicon film 22. Moreover, it is possible to preferentially promote etching of the polysilicon film 22 side portion to broaden the spacing of fellow polysilicon films 22 and suitably embed herein the polycrystalline silicon film 24 forming the control gate electrode 26. Therefore, it is possible for the floating gate electrode 22a and the control gate electrode 26 to be faced against each other in a broad area, and for capacitive coupling of the floating gate electrode 22a and the control gate electrode 26 to be suitably increased.

Moreover, as shown in FIG. 13, sometimes, if etching ends up progressing isotropically at the upper surface and side surfaces of the polysilicon film 22, the etching results in both side surfaces of the polysilicon film 22 approaching each other and the upper surface getting sharp. Sometimes, in such a case, an electric field concentrates in the floating gate electrode 22a upper portion, resulting in a leak current from the floating gate electrode 22a to the control gate electrode 26.

As shown in FIG. 14, in the present embodiment, etching of the upper surface of the polysilicon film 22 is suppressed, hence it is possible for both side surfaces of the polysilicon film 22 at the upper portion of the polysilicon film 22 to be prevented from approaching each other, whereby at least part of the upper surface of the floating gate electrode 22a may be configured to be parallel to the lower surface and may be configured to at least not be sharp. Therefore, concentration of an electric field to the floating gate electrode 22a upper portion can be prevented, and leak current can be lowered.

[Experiment Results]

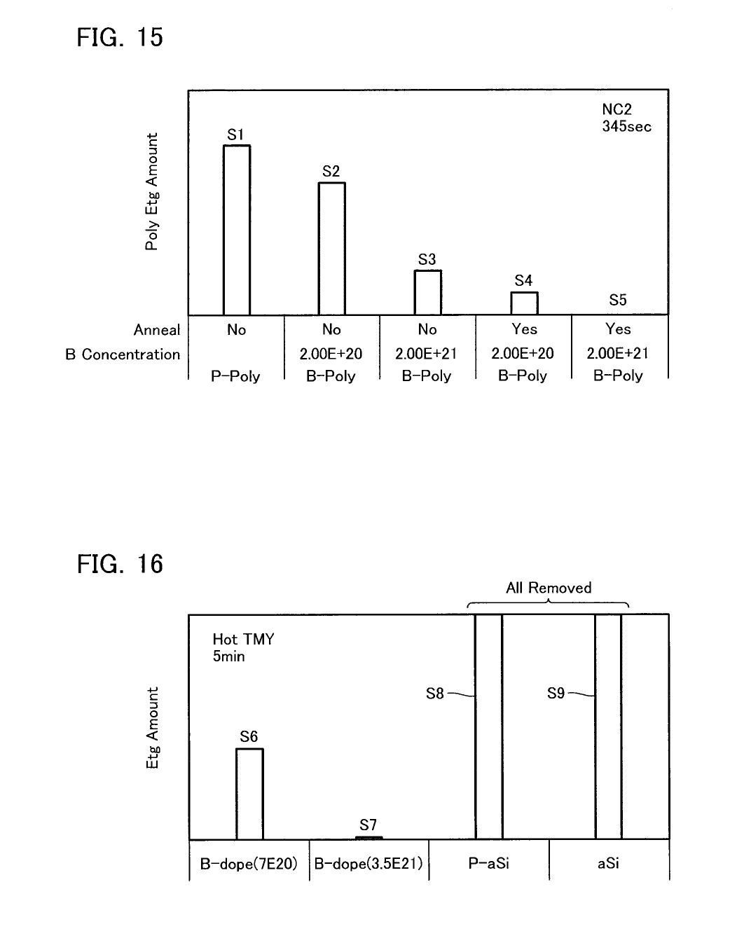

Next, results of an experiment performed by the inventors will be described with reference to FIGS. 15 and 16. FIGS. 15 and 16 are graphs each showing an etching amount when etching is performed on polysilicon under a plurality of different conditions.

As shown in FIG. 15, during the present experiment, the inventors produced a plurality of samples S1 to S5. A first sample S1 is polysilicon doped with phosphorus (P), and second through fifth samples S2 to S5 are polysilicon doped with boron (B). In addition, concentration of boron in the second and fourth samples S2 and S4 is 2×10²⁰, and concentration of boron in the third and fifth samples S3 and S5 is 2×10²¹. Moreover, in the first through third samples S1 to S3, annealing is not performed, and in the fourth and fifth samples S4 and S5, annealing is performed.

FIG. 15 shows an etching amount when etching employing NC2 (New Clean 2) has been performed for 345 seconds on these first through fifth samples S1 to S5. NC2 is a mixed liquid of TMY (trimethyl 2-hydroxyethyl ammonium hydroxide) and hydrogen peroxide.

As shown in FIG. 15, the second through fifth samples S2 to S5 doped with boron (B) are found to have an etching rate which is lower compared to that of the first sample S1 doped with phosphorus (P). Moreover, in the second and third samples S2 and S3, annealing is not performed, but in the third sample S3 whose boron concentration is 10 times higher compared to that of the second sample S2, the etching rate is about three times lower compared to that of the second sample S2. Furthermore, in the fourth and fifth samples S4 and S5, annealing is performed, but similarly to when annealing is not performed, likewise in the fifth sample S5 whose boron concentration is 10 times higher compared to that of the fourth sample S4, the etching rate is lower compared to that of the fourth sample S4. Note that as shown in FIG. 15, etching rate is lower when annealing is performed compared to when annealing is not performed.

Next, as shown in FIG. 16, the inventors further produced a plurality of samples S6 to S9. Sixth and seventh samples S6 and S7 are polysilicon doped with boron (B), an eighth sample S8 is amorphous silicon doped with phosphorus (P), and a ninth sample S9 is undoped amorphous silicon. Moreover, concentration of boron in the sixth sample S6 is 7×10²⁰, and concentration of boron in the seventh sample S7 is 3.5×10²¹.

FIG. 16 shows an etching amount when etching employing the above-mentioned TMY has been performed for five minutes on these sixth through ninth samples S6 to S9.

As shown in FIG. 16, the eighth and ninth samples S8 and S9 were all removed after five minutes from start of etching. In contrast, only part of the sixth and seventh samples S6 and S7 doped with boron (B) was removed. Moreover, in the seventh sample S7 whose boron concentration is five times higher compared to that of the sixth sample S6, the etching rate is lower compared to that of the sixth sample S6, even when etching has been performed employing TMY and not NC2.

From the above it was found that when etching is performed on polysilicon including boron, etching rate lowers as concentration of boron rises, and etching rate rises as concentration of boron lowers. Moreover, such an effect was found to be achievable if boron concentration is at least five times or more.

[Others]

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a semiconductor substrate;
a first gate insulating film formed on the semiconductor substrate;
a floating gate electrode formed arranged in a first direction on the first gate insulating film;
a second gate insulating film formed on an upper surface and a side surface of the floating gate electrode; and
a control gate electrode extending in the first direction and facing the upper surface and the side surface of the floating gate electrode via the second gate insulating film,
the floating gate electrode including boron, and
a concentration of boron in the floating gate electrode being higher with being further from the semiconductor substrate.

2. The nonvolatile semiconductor memory device according to claim 1, wherein
the floating gate electrode is configured from polysilicon.

3. The nonvolatile semiconductor memory device according to claim 1, wherein
the concentration of boron in the floating gate electrode differs by five times or more within the floating gate electrode.

4. The nonvolatile semiconductor memory device according to claim 1, wherein
at least part of the upper surface of the floating gate electrode is parallel to a lower surface of the floating gate electrode.

5. The nonvolatile semiconductor memory device according to claim 1, wherein
a width of the floating gate electrode decreases with a first inclination from a lower surface to a certain height and decreases with a second inclination smaller than the first inclination from the certain height to an upper portion.

6. The nonvolatile semiconductor memory device according to claim 1, wherein
an element isolation insulating film is embedded in a region of the semiconductor substrate between the floating gate electrodes adjacent in the first direction,
the second gate insulating film covers an upper surface of the element isolation insulating film, and
the control gate electrode contacts a portion of the second gate insulating film covering the upper surface of the element isolation insulating film.

7. A method of manufacturing a nonvolatile semiconductor memory device, comprising:
forming a first gate insulating film on a semiconductor substrate;
forming on the first gate insulating film a floating gate electrode formation layer which includes boron and in which a concentration of this boron is higher with being further from the semiconductor substrate;
dividing the floating gate electrode formation layer in a first direction;
removing at least part of a side portion of the floating gate electrode formation layer;
forming a second gate insulating film on an upper surface and a side surface of the floating gate electrode formation layer; and
forming a control gate electrode formation layer facing the upper surface and the side surface of the floating gate electrode formation layer via the second gate insulating film.

8. The method of manufacturing a nonvolatile semiconductor memory device according to claim 7, wherein
the floating gate electrode formation layer is configured from polysilicon.

9. The method of manufacturing a nonvolatile semiconductor memory device according to claim 7, wherein
the concentration of boron in the floating gate electrode formation layer differs by five times or more within the floating gate electrode formation layer.

10. The method of manufacturing a nonvolatile semiconductor memory device according to claim 7, further comprising,
after dividing the floating gate electrode formation layer:
forming an element isolation insulating film in a region of the semiconductor substrate between the divided floating gate electrode formation layers;
partially removing the element isolation insulating film and exposing at least part of the side surface of the divided floating gate electrode formation layer;
when forming the second gate insulating film, covering the element isolation insulating film by the second gate insulating film; and
when forming the control gate electrode formation layer, forming the control gate electrode formation layer so as to contact a portion of the second gate insulating film covering an upper surface of the element isolation insulating film.
